(19) United States
(12) Patent Application Publication
(10) Pub. No.: US 2026/0204224 A1
(43) Pub. Date: Jul. 16, 2026

(54) DISPLAY PANEL AND ELECTRONIC APPARATUS INCLUDING THE SAME

(71) Applicant: Samsung Display Co., Ltd., Yongin-Si (KR)

(72) Inventors: Danwon Lim, Yongin-si (KR); Hyunjoon Kim, Yongin-si (KR); Mindo Heo, Yongin-si (KR)

(21) Appl. No.: 19/318,990

(22) Filed: Sep. 4, 2025

(30) Foreign Application Priority Data
Jan. 13, 2025 (KR) 10-2025-0004983

(51) Int. Cl. G09G 3/3266; G09G 3/3233; H10K 59/131

(52) U.S. Cl. CPC G09G 3/3266; G09G 3/3233; H10K 59/131; G09G 2300/0426; G09G 2300/0842; G09G 2310/0286

(57) ABSTRACT

A display panel includes a substrate including a display area and a peripheral area outside the display area, a plurality of pixels arranged in the display area, a driving circuit arranged in the peripheral area and configured to output a plurality of gate signals to the plurality of pixels, and a plurality of clock lines arranged between the driving circuit and the display area and electrically connected to the driving circuit.

### CROSS-REFERENCE TO RELATED APPLICATION(S)

This application is based on and claims priority under 35 U.S.C. §119 to Korean Patent Application No. 10-2025-0004983, filed on January 13, 2025, in the Korean Intellectual Property Office, the disclosure of which is incorporated by reference herein in its entirety.

### BACKGROUND

### Field

The inventive concept of the disclosure relates to a display panel and an electronic apparatus including the same.

### Description of the Related Art

A display panel includes a plurality of pixels, a gate driving circuit, a data driving circuit, and a controller. Each of the pixels includes a light-emitting element and a pixel circuit configured to drive the light-emitting element. The gate driving circuit includes a plurality of stages, and each of the stages supplies a gate signal to the pixel circuit via a connected gate line in response to signals received from the controller.

### SUMMARY

The inventive concept of the disclosure includes a display panel, which outputs a high-quality image by reducing a rising time and a falling time of a gate signal, and an electronic apparatus including the same. However, this feature of the disclosure is not limited thereto, and other features not mentioned will be clearly understood by those skilled in the art from the description of the disclosure.

Additional aspects will be set forth in the description which follows and will be apparent from the description.

According to an embodiment, a display panel includes a substrate including a display area and a peripheral area outside the display area, a plurality of pixels arranged in the display area, a driving circuit arranged in the peripheral area and configured to output a plurality of gate signals to the plurality of pixels, a plurality of clock lines arranged between the driving circuit and the display area and electrically connected to the driving circuit.

In an embodiment, the display panel may further include a common voltage supply line arranged in the peripheral area and surrounding at least a portion of the display area. The connection electrode may be electrically connected to the common voltage supply line and overlapping at least a portion of the driving circuit. The connection electrode may be spaced apart from the plurality of clock lines in a plan view.

In an embodiment, the driving circuit may include a plurality of stages, and each of the plurality of stages may include a node control circuit configured to control voltage levels of a first control node and a second control node, and an output circuit including a pull-up transistor that is turned on or turned off in response to a voltage level of the first control node and a pull-down transistor that is turned on or turned off in response to a voltage level of the second control node.

In an embodiment, the output circuit may further include a buffer capacitor, and the connection electrode may be spaced apart from the buffer capacitor in the plan view.

In an embodiment, the connection electrode may overlap the node control circuit and may be spaced apart from the output circuit in the plan view.

In an embodiment, each of the plurality of pixels may include a pixel electrode, a common electrode arranged on the pixel electrode, and an emission layer arranged between the pixel electrode and the common electrode. The connection electrode may be electrically connected to the common electrode.

In an embodiment, the connection electrode may be arranged on a same layer as the pixel electrode.

In an embodiment, each of the plurality of clock lines may include a first wiring, a second wiring arranged on the first wiring, and a third wiring arranged on the second wiring. The first wiring, the second wiring, and the third wiring may be electrically connected to each other.

In an embodiment, the third wiring may be arranged on a same layer as the pixel electrode.

In an embodiment, the driving circuit may include a plurality of transistors, and the plurality of transistors may be oxide thin-film transistors.

According to an embodiment, an electronic apparatus includes a main processor, a display panel that displays an image based on an image data signal, and a controller electrically connected to the display panel and configured to receive an image signal from the main processor, generate the image data signal, and output a plurality of clock signals and the image data signal to the display panel. The display panel includes a substrate including a display area and a peripheral area outside the display area, a plurality of pixels arranged in the display area, a driving circuit arranged in the peripheral area and configured to output a plurality of gate signals to the plurality of pixels in response to the plurality of clock signals, clock lines arranged between the driving circuit and the display area and configured to transmit the plurality of clock signals to the driving circuit.

In an embodiment, the display panel may further include a common voltage supply line arranged in the peripheral area and surrounding at least a portion of the display area. The connection electrode may be electrically connected to the common voltage supply line and overlapping at least a portion of the driving circuit. The connection electrode may be spaced apart from the plurality of clock lines in a plan view.

In an embodiment, the driving circuit may include a plurality of stages, and each of the plurality of stages may include a node control circuit configured to control voltage levels of a first control node and a second control node, and an output circuit including a pull-up transistor that is turned on or turned off in response to a voltage level of the first control node and a pull-down transistor that is turned on or turned off in response to a voltage level of the second control node.

In an embodiment, the output circuit may further include a buffer capacitor, and the connection electrode may be spaced apart from the buffer capacitor in the plan view.

In an embodiment, in a plan view, the connection electrode may overlap the node control circuit and may be spaced apart from the output circuit in the plan view.

In an embodiment, each of the plurality of pixels may include a pixel electrode, a common electrode arranged on the pixel electrode, and an emission layer arranged between the pixel electrode and the common electrode. The connection electrode may be electrically connected to the common electrode.

In an embodiment, the connection electrode may be arranged on a same layer as the pixel electrode.

In an embodiment, each of the clock lines may include a first wiring, a second wiring arranged on the first wiring, and a third wiring arranged on the second wiring. The first wiring, the second wiring, and the third wiring may be electrically connected to each other.

In an embodiment, the third wiring may be arranged on a same layer as the pixel electrode.

In an embodiment, the driving circuit may include a plurality of transistors, and the plurality of transistors may be oxide thin-film transistors.

In an embodiment, the electronic apparatus may be one of an image display electronic apparatus, a wearable electronic apparatus, and a vehicle electronic apparatus.

Other aspects, features, and advantages other than those described above will become apparent from the following drawings, claims, and detailed description of the disclosure.

### BRIEF DESCRIPTION OF THE DRAWINGS

The above and other aspects, features, and advantages of embodiments of the disclosure will be more apparent with reference to the following description taken in conjunction with the accompanying drawings.

FIGS. 1A and 1B are schematic views showing a display panel according to an embodiment.

FIG. 2 is a schematic view showing a display panel according to an embodiment.

FIG. 3 is a schematic view showing a driving circuit according to an embodiment.

FIG. 4 is a schematic view showing a stage of a driving circuit according to an embodiment.

FIG. 5 is a schematic view showing driving circuits according to an embodiment.

FIGS. 6 and 7 are schematic views showing input signals and output signals of a driving circuit.

FIGS. 8A and 8B are schematic views showing an area Ⅰ of the display panel illustrated in FIG. 2.

FIG. 9 is a cross-sectional view schematically illustrating a display panel according to an embodiment.

FIG. 10 is a schematic view showing a portion of a display panel according to an embodiment.

FIG. 11 is a cross-sectional view schematically illustrating a display panel according to an embodiment.

FIG. 12A is a block diagram of an electronic apparatus according to an embodiment.

FIG. 12B shows schematic views of electronic apparatuses according to various embodiments.

### DETAILED DESCRIPTION

Hereinafter, embodiments of the disclosure are explained in detail with reference to the accompanying drawings. Like numerals refer to like elements throughout. In this regard, embodiments of the disclosure may have different forms and should not be construed as being limited to the descriptions set forth herein. Accordingly, the embodiments are merely described below, by referring to the drawings, to explain aspects of the inventive concept of the disclosure. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

It should be noted that as various modifications may be applied to the inventive concept of the disclosure, exemplary embodiments will be illustrated in the drawings and described in detail in the written description. The effects and features of the disclosure, as well as a method to achieve the same, will be clearer with reference to the detailed descriptions below with the drawings. However, the present embodiments may be implemented in various forms and should not be construed as limited to the embodiments presented below.

Hereinafter, embodiments of the disclosure will be described in detail with reference to the accompanying drawings. Those elements that are the same as or similar to in their functionalities or structures, etc. are denoted using the same reference numeral regardless of the figure number, and redundant descriptions thereof are omitted.

In the present specification, it will be understood that although the terms "first," "second," etc. may be used herein to describe various components, these components should not be limited by these terms. These terms are only used to distinguish one component from another.

In the present specification, the singular expression, such as “a” and “an,” used herein includes plural forms unless clearly specified otherwise in context.

In the present specification, it will be further understood that the terms, such as "comprises," “include,” or their variations, used herein may be construed as indicating the presence of stated features or components, but may not be construed to exclude the existence of or a possible addition of one or more other features or components.

In the present specification, it will be understood that when a layer, area, or component is referred to as being "formed on" another layer, area, or component, it can be directly or indirectly formed on the other layer, area, or component. That is, for example, intervening layers, areas, or components may be present.

In the present specification, it will be understood that when a layer, area, or component is referred to as being "connected to" another layer, area, or component, it can be directly or indirectly connected to the other layer, area, or component. That is, for example, intervening layers, areas, or components may be present therebetween. For example, in the present specification, when a layer, area, or component is referred to as being “electrically connected to” another layer, area, or component, the layers, areas, or components may not only be directly electrically connected, but may also be indirectly electrically connected via another layer, area, or component therebetween.

In the present specification, the expression "A and/or B" represents A, B, or A and B. In addition, the expression "at least one of A and B" represents A, B, or A and B.

In the present specification, the x direction, the y direction, and the z direction are not limited to three axes of the rectangular coordinate system, and may be interpreted in a broader sense. For example, the x direction, the y direction, and the z direction may be perpendicular to one another, or may represent different directions that are not perpendicular to one another.

In the present specification, the term "in a plan view" means that a target portion is viewed from above (for example, when viewed in a direction perpendicular to a top surface of a substrate), and the term "in a cross-section" means that a vertically cut cross-section of a target portion is viewed from a side.

In the present specification, when a first component is said to "overlap" a second component, it means that the first component is arranged above or under the second component such that they overlap each other at least partially in a plan view.

In the present specification, the term "on" used in connection with a state of a component may refer to an active state of the component, and the term "off" may refer to an inactive state of the component. The term "on" used in relation to a signal received by a component may denote a signal that activates the component, and the term "off" may denote a signal that deactivates the component. A component may be activated according to a high-level voltage or a low-level voltage. For example, a P-channel transistor (a P-type transistor) is activated according to a low-level voltage, and an N-channel transistor (an N-type transistor) is activated according to a high-level voltage. Therefore, it should be construed that "on" voltages applied to the P-channel and N-channel transistors are opposite to each other (low vs. high).

In the present specification, the order of the process or method understood in the description of the process, manufacturing method of an exemplary embodiment, etc. may be different from the described order. For example, two consecutively described processes may be performed substantially at the same time or performed in an order opposite to the described order.

Sizes of components in the drawings may be exaggerated or reduced for convenience of explanation. In other words, since sizes and thicknesses of components in the drawings are arbitrarily illustrated for convenience of explanation, the embodiments of the disclosure are not limited thereto.

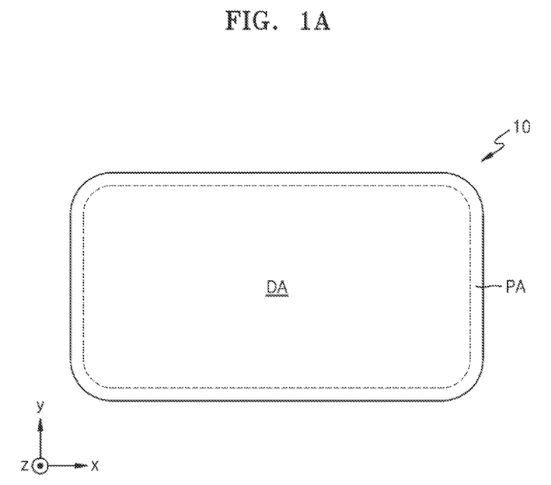

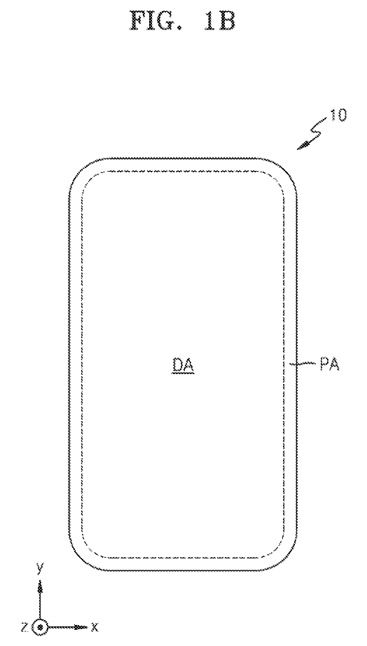

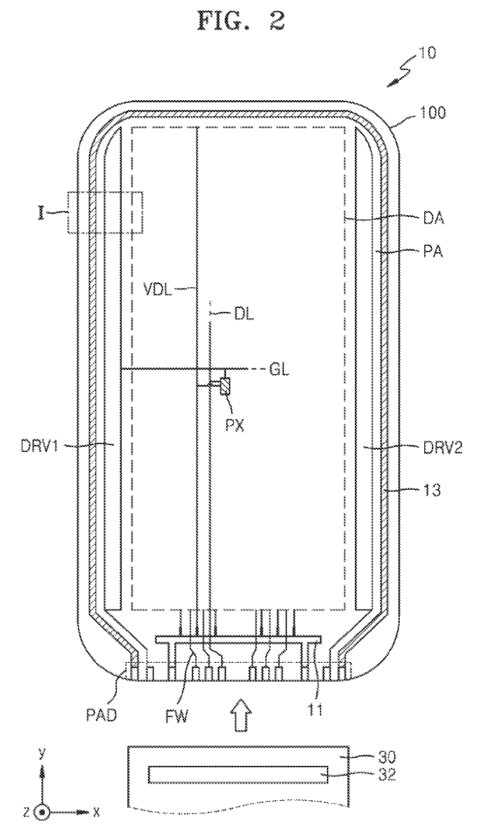

FIGS. 1A and 1B are schematic views showing a display panel according to an embodiment. FIG. 2 is a schematic view showing a display panel according to an embodiment.

Referring to FIGS. 1A and 1B, a display panel 10 may include a display area DA, which displays an image, and a peripheral area PA outside the display area DA. At least a portion of the display area DA may be surrounded by the peripheral area PA.

In a plan view, the display area DA may have an approximately rectangular shape. However, the shape of the display area DA is not limited thereto. For example, the display area DA may have a polygonal shape such as a triangle, a pentagon, or a hexagon, or may have a circular shape, an elliptical shape, or an irregular shape. The display area DA may have rounded corners. In an embodiment, the display panel 10 may include the display area DA having a length in an x direction greater than a length in a y direction, as shown in FIG. 1A. In an embodiment, the display panel 10 may include the display area DA having a length in the y direction greater than a length in the x direction, as shown in FIG. 1B.

Referring to FIG. 2, various components of the display panel 10 may be arranged on a substrate 100. The display area DA and the peripheral area PA surrounding at least a portion of the display area DA may be defined on the substrate 100. In other words, the substrate 100 may include the display area DA and the peripheral area PA outside the display area DA.

A plurality of pixels PX may be arranged in the display area DA. Each of the pixels PX may be connected to a corresponding gate line among a plurality of gate lines GL and a corresponding data line among a plurality of data lines DL. Each pixel PX includes a light-emitting diode, such as an organic light-emitting diode, an inorganic light-emitting diode or others, as a display element (a light-emitting element), and the light-emitting diode may be connected to a pixel circuit. Hereinafter, the plurality of pixels PX is described as including an organic light-emitting diode for the convenience of the description.

Each of the pixel circuits configured to drive each of the pixels PX may be electrically connected to peripheral circuits arranged in the peripheral area PA. A first gate driving circuit DRV1, a second gate driving circuit DRV2, a terminal unit PAD, a driving voltage supply line 11, and a common voltage supply line 13 may be arranged in the peripheral area PA.

The first gate driving circuit DRV1 and the second gate driving circuit DRV2 may be arranged to face each other with the display area DA therebetween. The pixels PX in the display area DA may be electrically connected to the first gate driving circuit DRV1 and the second gate driving circuit DRV2. The first gate driving circuit DRV1 and the second gate driving circuit DRV2 may be connected to the plurality of gate lines GL and may apply a gate signal to each of the pixel circuits via the gate lines GL.

The terminal unit PAD may be arranged on one side of the substrate 100. The terminal unit PAD may be exposed without being covered by an insulating layer and may be connected to a display circuit board 30. The display circuit board 30 may be attached to one side of the display panel 10. The display circuit board 30 may be a flexible printed circuit board (FPCB) that is bendable, a rigid printed circuit board (PCB) that is hard to be bent, or a composite printed circuit board including both a rigid PCB and an FPCB.

A display driving portion 32 may be arranged on the display circuit board 30. The display driving portion 32 includes a data driving circuit, and the data driving circuit may be connected to the plurality of data lines DL and may be configured to generate a data signal. The generated data signal may be transmitted to the pixel circuits of the pixels PX via a fan-out line FW and a data line DL connected to the fan-out line FW.

The display driving portion 32 may include a power supply circuit, and the power supply circuit may be configured to supply a first power voltage to the pixel circuits through the driving voltage supply line 11 and supply a second power voltage to the pixel circuits through the common voltage supply line 13. The first power voltage may be applied to the pixel circuits of the pixels PX via a driving voltage line VDL connected to the driving voltage supply line 11, and the second power voltage may be applied to a common electrode of the organic light-emitting diode via the common voltage supply line 13.

The display driving portion 32 may include a controller, and the controller may generate control signals transmitted to the first gate driving circuit DRV1, the second gate driving circuit DRV2, the data driving circuit, and the power supply circuit, respectively.

The driving voltage supply line 11 is connected to the terminal unit PAD, may be arranged at a lower side of the display area DA, and may extend in the x direction. The common voltage supply line 13 is connected to the terminal unit PAD, has a loop shape with one side open, and may partially surround the display area DA.

A part or all of the first gate driving circuit DRV1 and the second gate driving circuit DRV2 may be formed directly in the peripheral area PA of the substrate 100 during a process of forming a pixel circuit in the display area DA of the substrate 100. The display driving portion 32 may be formed as an integrated circuit chip and arranged on the display circuit board 30 that is electrically connected to the terminal unit PAD arranged on one side of the substrate 100. In an embodiment, the display driving portion 32 may be arranged directly on the substrate 100 by using a chip on glass (COG) or chip on plastic (COP) method.

In an embodiment, a plurality of transistors included in the pixel circuits of the display area DA and a plurality of transistors included in the peripheral circuits of the peripheral area PA, for example, the first gate driving circuit DRV1 and the second gate driving circuit DRV2, may each be an N-channel thin-film transistor. The plurality of transistors included in the peripheral circuits, located in the peripheral area PA, and the plurality of transistors included in the pixel circuits, located in the display area DA, may be formed simultaneously through the same process. However, the inventive concept of the disclosure is not limited thereto. For example, the plurality of transistors included in the pixel circuits of the display area DA and the plurality of transistor included in the peripheral circuits of the peripheral area PA may each be a P-channel thin-film transistor. For example, some of the plurality of transistors included in the pixel circuits of the display area DA and the plurality of transistors included in the peripheral circuits of the peripheral area PA may each be an N-channel thin-film transistor, and the others may be a P-channel thin-film transistor.

The N-channel thin-film transistor may be an oxide thin-film transistor. The oxide thin-film transistor may include an oxide semiconductor layer. Oxide semiconductors may include Zn oxide, In-Zn oxide, or Ga-In-Zn oxide. In an embodiment, an oxide semiconductor may be an In-Ga-Zn-O semiconductor containing metals such as indium (In) and gallium (Ga) in ZnO. In an embodiment, the oxide thin-film transistor may be a low-temperature polycrystalline oxide (LTPO) thin-film transistor.

The P-channel thin-film transistor may be a silicon thin-film transistor. The silicon thin-film transistor may be a low-temperature polysilicon (LTPS) thin-film transistor in which a semiconductor layer includes amorphous silicon or polysilicon.

Although FIG. 2 illustrates that one pixel PX is connected to one gate line GL, the embodiment of the disclosure is not limited thereto. For example, one pixel PX may be connected to one or more gate lines GL.

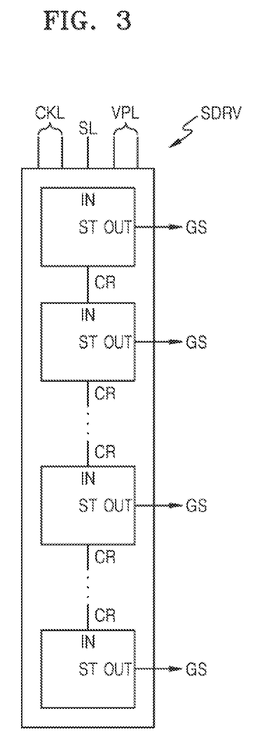

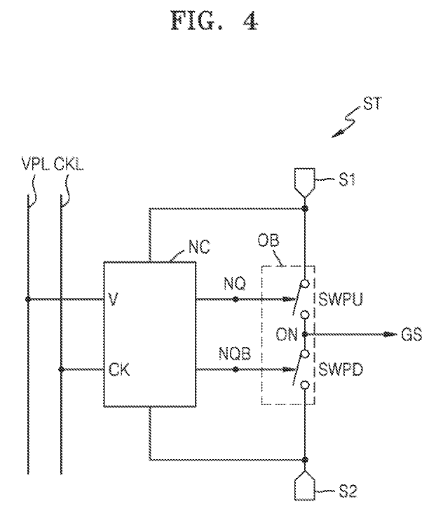

FIG. 3 is a schematic view showing a driving circuit according to an embodiment. FIG. 4 is a schematic view showing a stage of a driving circuit according to an embodiment.

Each of the first gate driving circuit DRV1 and the second gate driving circuit DRV2 shown in FIG. 2 includes at least one driving circuit SDRV, and a driving circuit SDRV may include a plurality of stages ST. As shown in FIG. 3, each of the stages ST may be connected to at least one clock line CKL, at least one voltage line VPL, and a start signal line SL. Each stage ST may receive at least one clock signal from the at least one clock line CKL and receive at least one voltage signal from the at least one voltage line VPL. The start signal line SL is connected to an input terminal IN of a first stage ST among the plurality of stages ST, and a start signal may be input to the first stage ST of the driving circuit SDRV through the start signal line SL. A carry signal CR output from a previous stage ST may be input as a start signal to the input terminal IN of each subsequent stage ST, from a second stage ST onward among the plurality of stages ST. A gate line is connected to an output terminal OUT of each of the plurality of stages ST, and a gate signal GS may be output via the gate line. In an embodiment, the carry signal CR may be the gate signal GS output from a previous stage ST.

Referring to FIG. 4, a stage ST may include a node control circuit NC configured to control voltage levels of a first control node NQ and a second control node NQB, and an output circuit OB including a pull-up transistor SWPU and a pull-down transistor SWPD.

A voltage terminal V of the node control circuit NC is connected to a voltage line VPL, and a voltage signal having a first voltage level or a second voltage level may be input from the voltage line VPL. A clock terminal CK of the node control circuit NC is connected to a clock line CKL, and a clock signal may be input from the clock line CKL.

The pull-up transistor SWPU is turned on or turned off in response to a voltage level of the first control node NQ. When the pull-up transistor SWPU is turned on, the pull-up transistor SWPU may connect a first terminal S1 to an output node ON, and the stage ST may output, as the gate signal GS, a first signal applied to the first terminal S1. The pull-down transistor SWPD is turned on or turned off in response to a voltage level of the second control node NQB. When the pull-down transistor SWPD is turned on, the pull-down transistor SWPD may connect a second terminal S2 to the output node ON, and the stage ST may output, as the gate signal GS, a second signal applied to the second terminal S2. In an embodiment, the first signal and the second signal may be a voltage signal having the first voltage level or the second voltage level, or may be a clock signal in which the first voltage level and the second voltage level alternate. In an embodiment, the first voltage may have a high voltage level, and the second voltage may have a low voltage level.

In an embodiment, each of the pull-up transistor SWPU and the pull-down transistor SWPD may be an oxide thin-film transistor including an oxide semiconductor layer.

FIGS. 3 and 4 illustrate the electrical connection relationships of each component including in one stage ST for the purpose of explanation. Thus, an actual arrangement of each component on the display panel 10 may be differ from those shown in FIGS. 3 and 4.

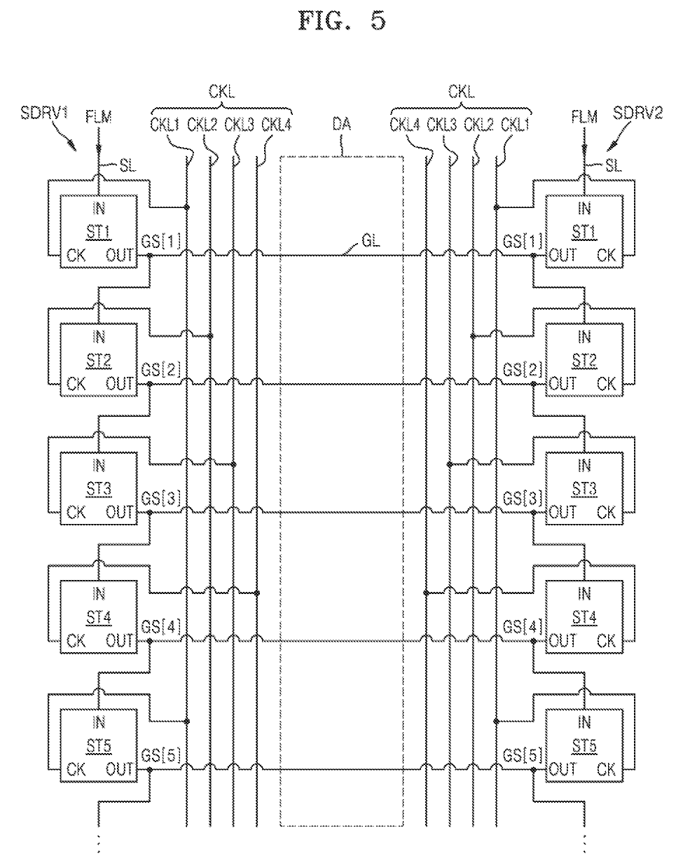

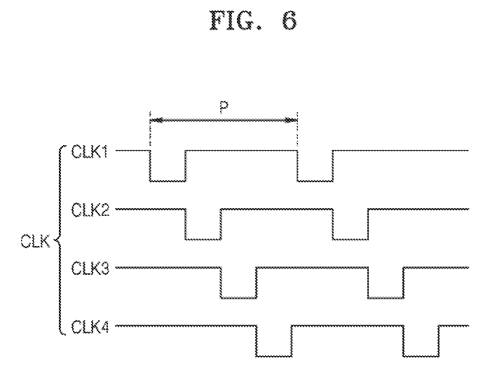

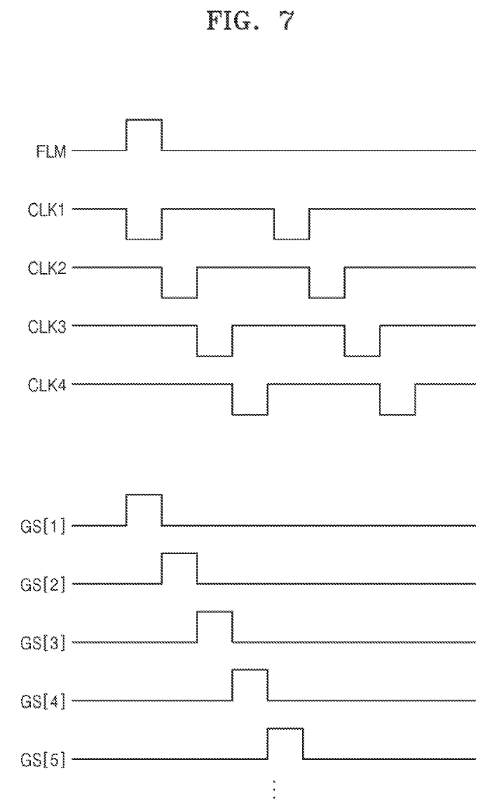

FIG. 5 is a schematic view showing driving circuits according to an embodiment. FIGS. 6 and 7 are schematic views showing input signals and output signals of a driving circuit. Hereinafter, for convenience of explanation, descriptions about a voltage signal input from the power supply circuit will be omitted.

In an embodiment, the first gate driving circuit DRV1 may include a first driving circuit SDRV1 configured to output the gate signal GS, and the second gate driving circuit DRV2 may include a second driving circuit SDRV2 configured to output the gate signal GS.

As shown in FIG. 5, the first driving circuit SDRV1 and the second driving circuit SDRV2 may be arranged in the peripheral area PA outside the display area DA, and the display area DA may be arranged between the first driving circuit SDRV1 and the second driving circuit SDRV2. In other words, the first driving circuit SDRV1 may be arranged at the left side (-x direction) of the display area DA, and the second driving circuit SDRV2 may be arranged at the right side (x direction) of the display area DA. The first driving circuit SDRV1 and the second driving circuit SDRV2 may be arranged symmetrically to each other with the display area DA therebetween.

Each of the first driving circuit SDRV1 and the second driving circuit SDRV2 may include a plurality of stages ST1, ST2, ST3, ST4, and ST5. In an embodiment, the plurality of stages ST1, ST2, ST3, ST4, and ST5 of the first driving circuit SDRV1 and the plurality of stages ST1, ST2, ST3, ST4, and ST5 of the second driving circuit SDRV2 may correspond to each other in a one-to-one manner. Output terminals OUT of corresponding stages may be connected to the same gate line GL. For example, the second stage ST2 of the first driving circuit SDRV1 and the second stage ST2 of the second driving circuit SDRV2 may be connected to a gate line GL arranged in a second row.

The plurality of stages ST1, ST2, ST3, ST4, and ST5 may be connected to clock lines CKL to which a clock signal CLK is input. As shown in FIG. 5, in an embodiment, the clock signal CLK may include first to fourth clock signals CLK1, CLK2, CLK3, and CLK4. The clock lines CKL may include a first clock line CKL1 configured to transmit the first clock signal CLK1, a second clock line CKL2 configured to transmit the second clock signal CLK2, a third clock line CKL3 configured to transmit the third clock signal CLK3, and a fourth clock line CKL4 configured to transmit the fourth clock signal CLK4. Each of the first to fourth clock lines CKL1, CKL2, CKL3, and CKL4 may be sequentially connected to every four stages among the plurality of stages ST1, ST2, ST3, ST4, and ST5, and the first to fourth clock signals CLK1, CLK2, CLK3, and CLK4 may be sequentially input.

Each of the first to fourth clock signals CLK1, CLK2, CLK3, and CLK4 may be a square wave signal that alternates between a high-level voltage and a low-level voltage. The first to fourth clock signals CLK1, CLK2, CLK3, and CLK4 may have the same waveform and a same period P, but each of those phases is shifted (or phase delayed) by 1/4 period from those of other clock signals. For example, the second clock signal CLK2 is phase shifted by 1/4 period with reference to the first clock signal CLK1, the third clock signal CLK3 is phase shifted by 1/4 period from the second clock signal CLK2, and the fourth clock signal CLK4 is phase shifted by 1/4 period from the third clock signal CLK3.

The start signal line SL may be connected to the input terminal IN of the first stage ST1 among the plurality of stages ST1, ST2, ST3, ST4, and ST5, and a start signal FLM may be input via the start signal line SL. An output signal, that is the gate signal GS, from a previous stage may be input to the input terminal IN of one of subsequent stages ST2, ST3, ST4, and ST5. For example, a gate signal GS[1] output from the first stage ST1 may be input to the input terminal IN of the second stage ST2, and a gate signal GS[2] output from the second stage ST2 may be input to the input terminal IN of the third stage ST3. However, the inventive concept of the disclosure is not limited thereto. For example, each of the plurality of stages ST1, ST2, ST3, ST4, and ST5 may further output a carry signal, and a carry signal output from a previous stage may be input to the input terminal IN of one of subsequent stages ST2, ST3, ST4, and ST5.

The plurality of stages ST1, ST2, ST3, ST4, and ST5 may be driven in synchronization with the start signal FLM or an output signal from a previous stage, and may generate gate signals GS[1], GS[2], GS[3], GS[4], and GS[5] and sequentially output them to gate lines GL. As shown in FIG. 7, the gate signals GS[1], GS[2], GS[3], GS[4], and GS[5] output from the plurality of stages ST1, ST2, ST3, ST4, and ST5 may be sequentially shifted in response to the first to fourth clock signals CLK1, CLK2, CLK3, and CLK4. FIG. 7 illustrates an example in which the plurality of stages ST1, ST2, ST3, ST4, and ST5 sequentially output the high-level gate signals GS[1], GS[2], GS[3], GS[4], and GS[5].

The gate signal GS output from the first driving circuit SDRV1 and the gate signal GS output from the second driving circuit SDRV2 may be the same as each other. The gate signal GS output from the plurality of stages ST1, ST2, ST3, ST4, and ST5 of the first driving circuit SDRV1 and the gate signal GS output from the plurality of stages ST1, ST2, ST3, ST4, and ST5 of the second driving circuit SDRV2 may be the same as each other. In this context, "the same gate signals " may imply that the transistors in the pixels receiving these gate signals may be identical to each other. For example, a gate signal output from the first stage ST1 may be input to a gate of a switching transistor, which is configured to transmit a data signal, included in a pixel circuit in a first row, and a gate signal output from the second stage ST2 may be input to a gate of a switching transistor, which is configured to transmit a data signal, included in a pixel circuit in a second row.

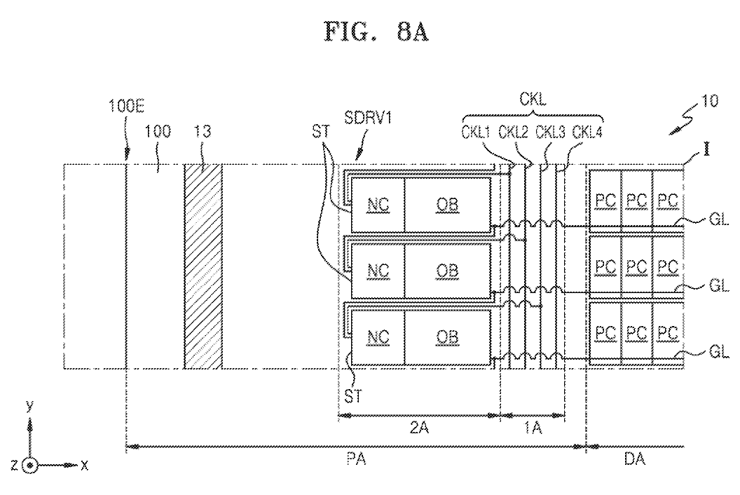

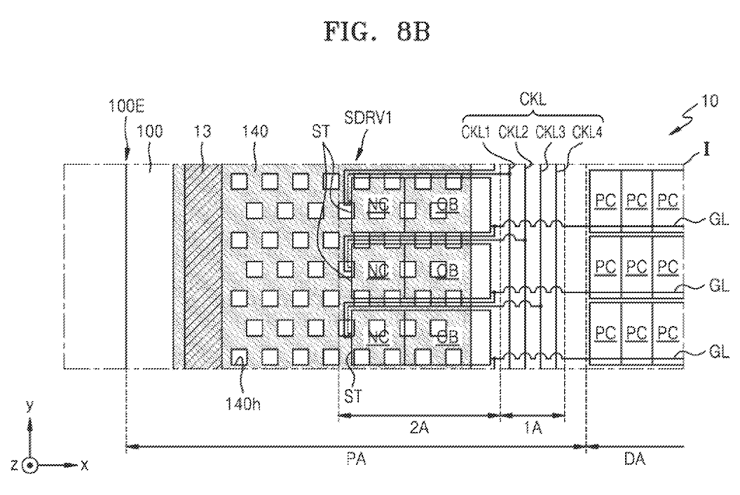

FIGS. 8A and 8B are schematic views showing an area Ⅰ of the display panel illustrated in FIG. 2. FIG. 8A schematically shows the common voltage supply line 13, the first driving circuit SDRV1, the clock lines CKL, and pixel circuits PC. FIG. 8B is similar to FIG. 8A, but additionally shows a first connection electrode 140.

Referring to FIG. 8A, various components of the display panel 10 may be arranged on the substrate 100. The display area DA and the peripheral area PA surrounding at least a portion of the display area DA may be defined on the substrate 100.

A plurality of pixels may be arranged in the display area DA. Each of the plurality of pixels may include an organic light-emitting diode and a pixel circuit PC configured to drive the organic light-emitting diode. A plurality of pixel circuits PC may be arranged in the form of a matrix in a first direction (for example, the x direction) and a second direction (for example, the y direction). The pixel circuits PC arranged in the same row may be electrically connected to the same gate line GL. Switching transistors electrically connected to the same gate line GL may be simultaneously turned on or turned off in response to a gate signal transmitted via the gate line GL.

The common voltage supply line 13 may be arranged in the peripheral area PA. The common voltage supply line 13 may receive the second power voltage from the power supply circuit. The common voltage supply line 13 may extend along an edge 100E of the substrate 100 and may have a loop shape with one side open. The common voltage supply line 13 may partially surround the display area DA.

The clock lines CKL may extend in the second direction (for example, the y direction) and may be arranged in the peripheral area PA, which is adjacent to the display area DA. The clock lines CKL may include the first clock line CKL1 configured to transmit a first clock signal, the second clock line CKL2 configured to transmit a second clock signal, the third clock line CKL3 configured to transmit a third clock signal, and the fourth clock line CKL4 configured to transmit a fourth clock signal. The first to fourth clock signals may be signals having the same waveform and the same period, but with a shifted phase by 1/4 period from each other, as explained above.

The first driving circuit SDRV1 may be arranged in the peripheral area PA. The first driving circuit SDRV1 may include a plurality of stages ST. Each of the plurality of stages ST may be connected to a corresponding clock line CKL. For example, each of the first to fourth clock lines CKL1, CKL2, CKL3, and CKL4 may be sequentially connected to every four stages among the plurality of stages ST.

Each of the plurality of stages ST may include the node control circuit NC and the output circuit OB. The node control circuit NC may be arranged closer to the edge 100E of the substrate 100 than the output circuit OB. The output circuit OB may be arranged closer to the display area DA than the node control circuit NC. The clock lines CKL may be arranged at a side closer to the output circuit OB.

As described above with reference to FIG. 4, the node control circuit NC may control voltage levels of a first control node and a second control node based on a voltage signal and a clock signal. The output circuit OB may include a pull-up transistor that is turned on or turned off in response to a voltage level of the first control node, and a pull-down transistor that is turned on or turned off in response to a voltage level of the second control node. The output circuit OB may be electrically connected to a corresponding gate line GL and may supply a gate signal to the pixel circuits PC in the same row via the gate line GL.

A start signal line may be connected to an input terminal of a first stage among the plurality of stages ST, and a start signal may be input via the start signal line. An output terminal of a previous stage may be electrically connected to an input terminal of a subsequent stage ST, from a second stage among the plurality of stages ST, via a connection wiring. An output signal, for example, a gate signal or a carry signal, from a previous stage may be input to an input terminal of a subsequent stage ST, from the second stage among the plurality of stages ST.

The peripheral area PA may include a first area 1A and a second area 2A. The first area 1A may be an area where the clock lines CKL are arranged, and the second area 2A may be an area where the first driving circuit SDRV1 is arranged. The first area 1A may be arranged closer to the display area DA than the second area 2A. In other words, the clock lines CKL may be arranged between the first driving circuit SDRV1 and the display area DA. The common voltage supply line 13 may be arranged closer to the edge 100E of the substrate 100 than the first driving circuit SDRV1. The common voltage supply line 13 may be arranged outside the second area 2A (for example, the common voltage supply line 13 is arranged in a region closer to the edge 100E of the substrate 100).

Referring to FIG. 8B, the first connection electrode 140 may be arranged in the peripheral area PA. The first connection electrode 140 may be arranged on the common voltage supply line 13 and the first driving circuit SDRV1 and may electrically connect a common electrode of the organic light-emitting diode to the common voltage supply line 13.

In a plan view, the first connection electrode 140 may overlap the common voltage supply line 13 and the first driving circuit SDRV1. An inner edge of the first connection electrode 140 may be arranged on the first driving circuit SDRV1. For example, the first connection electrode 140 may cover the entire node control circuit NC and cover a part of the output circuit OB. In a plan view, the first connection electrode 140 may be spaced apart from the clock lines CKL. In other words, the first connection electrode 140 may not overlap the clock lines CKL. The first connection electrode 140 may define a plurality of holes 140h for discharging gas generated from lower organic layers.

The first driving circuit SDRV1 may output gate signals to the pixel circuits PC via gate lines GL. Each of the gate signals may be a square wave signal that alternates between a high-level voltage and a low-level voltage. To secure an on-voltage period in one horizontal period 1H which is required to write data into each of the pixel circuits PC, a reduction in a rising time and a falling time of a gate signal is required. According to embodiments, a capacitance between the first connection electrode 140 and the clock lines CKL may be reduced by arranging the first connection electrode 140 and the clock lines CKL apart from each other in a plan view. As a capacitance of the clock lines CKL decreases, a rising time and a falling time of a gate signal output from the first driving circuit SDRV1 can be reduced, thereby achieving an output of a high-quality image from the display panel 10.

As the second power voltage is supplied to the common electrode of the organic light-emitting diode via the first connection electrode 140, it is necessary to secure a sufficient contact area between the first connection electrode 140 and the common electrode. By arranging the clock lines CKL adjacent to the display area DA, the contact area between the first connection electrode 140 and the common electrode can be sufficiently increased.

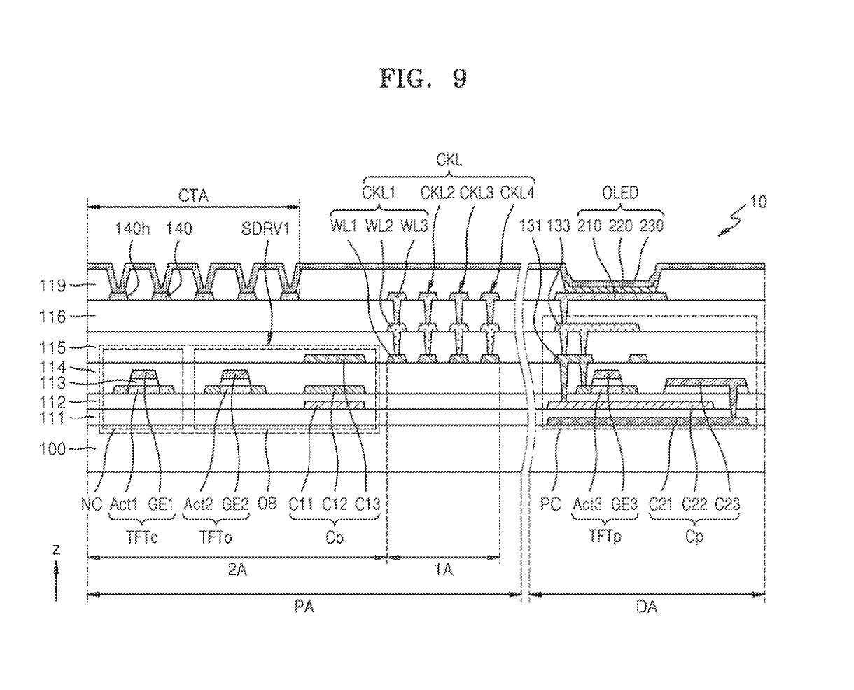

FIG. 9 is a cross-sectional view schematically illustrating a display panel according to an embodiment.

Referring to FIG. 9, the display panel 10 may include the display area DA, in which pixels are arranged, and the peripheral area PA outside the display area DA. Because components of the display panel 10 are arranged on the substrate 100, the display area DA and the peripheral area PA surrounding at least a portion of the display area DA may be defined on the substrate 100.

Each of the pixels arranged in the display area DA may include the pixel circuit PC and an organic light-emitting diode OLED electrically connected to the pixel circuit PC. The pixel circuit PC may include a first thin-film transistor TFTp and a first capacitor Cp. The first thin-film transistor TFTp may be a driving transistor configured to transmit a driving current to the organic light-emitting diode OLED, and the first capacitor Cp may be a storage capacitor.

The first driving circuit SDRV1 and the clock lines CKL may be arranged in the peripheral area PA. The first driving circuit SDRV1 may include a plurality of stages, and each of the stages may include the node control circuit NC and the output circuit OB. The node control circuit NC may include a second thin-film transistor TFTc, and the output circuit OB may include a third thin-film transistor TFTo and a second capacitor Cb (a buffer capacitor). The clock lines CKL may include the first to fourth clock lines CKL1, CKL2, CKL3, and CKL4.

The substrate 100 may include a glass material, a ceramic material, a metal material. The substrate 100 may include a flexible or bendable material. When the substrate 100 is flexible or bendable, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate.

The substrate 100 may have a single-layer structure or a multilayer structure. In an embodiment, the substrate 100 may have a multilayer structure in which an inorganic layer is arranged between base layers including polymer resin.

In the display area DA, a first buffer layer 111 may be arranged on the substrate 100, a second buffer layer 112 may be arranged on the first buffer layer 111. Each of the first buffer layer 111 and the second buffer layer 112 may include an inorganic material such as an oxide or a nitride, an organic material, or an organic-inorganic composite material, and may have a single-layered or multilayer structure including an inorganic material and an organic material.

A first electrode C21 of the first capacitor Cp may be arranged between the substrate 100 and the first buffer layer 111, and a second electrode C22 of the first capacitor Cp may be arranged between the first buffer layer 111 and the second buffer layer 112. In an embodiment, the first electrode C21 may be electrically connected to a power line configured to transmit the first power voltage. In an embodiment, the second electrode C22 of the first capacitor Cp may be integrally provided with a lower gate electrode of the first thin-film transistor TFTp.

A semiconductor layer Act3 of the first thin-film transistor TFTp may be arranged on the second buffer layer 112. The semiconductor layer Act3 of the first thin-film transistor TFTp may include an oxide semiconductor material. The oxide semiconductor material may include an oxide of at least one material selected from a group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The oxide semiconductor material may be In-Ga-Zn-O (IGZO), In-Sn-Zn-O (ITZO), or In-Ga-Sn-Zn-O (IGTZO).

The semiconductor layer Act3 of the first thin-film transistor TFTp may include a channel area, and a source area and a drain area arranged at opposite sides of the semiconductor layer Act3. An upper gate electrode GE3 of the first thin-film transistor TFTp may overlap the channel area of the semiconductor layer Act3. The upper gate electrode GE3 may include molybdenum (Mo), aluminum (Al), copper (Cu), or titanium (Ti), and may be formed as a single layer or a multilayer. A gate insulating layer 113 may be arranged between the semiconductor layer Act3 and the upper gate electrode GE3 of the first thin-film transistor TFTp. The gate insulating layer 113 may include an inorganic insulating material including silicon oxide, silicon nitride, silicon oxynitride, or aluminum oxide. In an embodiment, the gate insulating layer 113 may be patterned to have a shape corresponding to a shape of a conductive layer arranged on the gate insulating layer 113.

A third electrode C23 of the first capacitor Cp may be arranged on the second buffer layer 112. The third electrode C23 may be arranged on the same layer as the upper gate electrode GE3 of the first thin-film transistor TFTp. In the present specification, the expression "A and B are arranged on the same layer" may mean that A and B are formed by the same process, thus including substantially the same material and having the same layer structure and physical properties. The gate insulating layer 113 may be arranged between the second buffer layer 112 and the third electrode C23 of the first capacitor Cp.

In a plan view, the first electrode C21, the second electrode C22, and the third electrode C23 of the first capacitor Cp may overlap one another. In an embodiment, the first electrode C21 and the third electrode C23 of the first capacitor Cp may be electrically connected to each other.

An interlayer insulating layer 114 may be arranged on the upper gate electrode GE3 of the first thin-film transistor TFTp and the third electrode C23 of the first capacitor Cp. The interlayer insulating layer 114 may include an inorganic material such as an oxide or a nitride, an organic material, or an organic-inorganic composite material, and may have a single-layered or multilayer structure including an inorganic material and an organic material.

A second connection electrode 131 may be arranged on the interlayer insulating layer 114. The second connection electrode 131 may be electrically connected to the source area (or the drain area) of the first thin-film transistor TFTp via a contact hole passing through the interlayer insulating layer 114. A first planarization layer 115 may be arranged on the second connection electrode 131, and a third connection electrode 133 may be arranged on the first planarization layer 115. The third connection electrode 133 may be electrically connected to the second connection electrode 131 via a contact hole passing through the first planarization layer 115. A second planarization layer 116 may be arranged on the third connection electrode 133.

The second connection electrode 131 and the third connection electrode 133 may include a conductive material including molybdenum (Mo), aluminum (Al), copper (Cu), titanium (Ti), etc., and may be formed as a multilayer or single layer including the above material. For example, the second connection electrode 131 and the third connection electrode 133 may have a multilayer structure of Ti/Al/Ti.

Each of the first planarization layer 115 and the second planarization layer 116 may include an organic insulating material, such as polymethylmethacrylate (PMMA), polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a blend thereof.

The organic light-emitting diode OLED may be arranged on the second planarization layer 116. The organic light-emitting diode OLED may include a pixel electrode 210, an emission layer 220, and a common electrode 230.

The pixel electrode 210 may be arranged on the second planarization layer 116. The pixel electrode 210 may be electrically connected to the third connection electrode 133 via a contact hole passing through the second planarization layer 116. The pixel electrode 210 may be electrically connected to the first thin-film transistor TFTp of the pixel circuit PC via the second connection electrode 131 and the third connection electrode 133.

The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. The pixel electrode 210 may further include a conductive oxide layer above and/or under the above-described reflective film. The conductive oxide layer may include indium tin oxide, indium zinc oxide, zinc oxide, indium oxide, indium gallium oxide, and/or aluminum zinc oxide. In an embodiment, the pixel electrode 210 may have a three-layer structure of ITO/Ag/ITO.

A bank layer 119 may be arranged on the pixel electrode 210. An opening extending to at least a portion of the pixel electrode 210 may be defined in the bank layer 119. A central portion of the pixel electrode 210 may be exposed through the opening of the bank layer 119. The bank layer 119 may prevent an arc or the like from occurring on an edge of the pixel electrode 210 because the bank layer 119 increases a distance between the edge of the pixel electrode 210 and the common electrode 230 above the pixel electrode 210. The opening in the bank layer 119 may define an emission area of the organic light-emitting diode OLED.

The bank layer 119 may include an organic insulating material such as polyimide, polyamide, acrylic resin, benzocyclobutene, hexamethyldisiloxane (HMDSO), or phenolic resin. The bank layer 119 may be formed by a method such as spin coating. In an embodiment, the bank layer 119 may include a light-blocking material and may be black. The light-blocking material may include resin or paste including carbon black, carbon nanotubes, or black dye, metal particles such as nickel (Ni), aluminum (Al), molybdenum (Mo) or an alloy thereof, metal oxide particles (for example, chromium oxide), or metal nitride particles (for example, chromium nitride). When the bank layer 119 includes a light-blocking material, reflection of light by metal components arranged under the bank layer 119 may be reduced.

The emission layer 220 may include an organic material including a fluorescent or phosphorescent material emitting red light, green light, blue light, or white light. The emission layer 220 may be a low-molecular-weight organic material or a polymer organic material, and functional layers, such as a hole transport layer, a hole injection layer, an electron transport layer or an electron injection layer, may selectively be further arranged under and above the emission layer 220. The emission layer 220 may have a shape patterned to correspond to the pixel electrode 210. A functional layer such as a hole transport layer may be integrally provided on a plurality of pixel electrodes 210.

The common electrode 230 may be arranged on the emission layer 220. The common electrode 230 may include a conductive material having a low work function. For example, the common electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or alloys thereof. The common electrode 230 may further include a layer including ITO, IZO, ZnO or In₂O₃ on the (semi-)transparent layer including the above-described material. In an embodiment, the common electrode 230 may be arranged on the plurality of pixel electrodes 210 and entirely cover the display area DA.

FIG. 9 illustrates that the organic light-emitting diode OLED is electrically connected to the first thin-film transistor TFTp via the second connection electrode 131 and the third connection electrode 133, but the disclosure is not limited thereto. In an embodiment, at least one switching transistor may be electrically connected between the first thin-film transistor TFTp and the second connection electrode 131.

The peripheral area PA may include the first area 1A and the second area 2A outside the first area 1A. The clock lines CKL may be arranged in the first area 1A, and the first driving circuit SDRV1 may be arranged in the second area 2A. The first driving circuit SDRV1 may include a plurality of stages, and each of the stages may include the node control circuit NC and the output circuit OB. The node control circuit NC may include the second thin-film transistor TFTc, and the output circuit OB may include the third thin-film transistor TFTo and the second capacitor Cb.

The first buffer layer 111 may be arranged on the substrate 100, and a first electrode C11 of the second capacitor Cb may be arranged on the first buffer layer 111. The first electrode C11 of the second capacitor Cb may be arranged on the same layer as the second electrode C22 of the first capacitor Cp.

A semiconductor layer Act1 of the second thin-film transistor TFTc, a semiconductor layer Act2 of the third thin-film transistor TFTo, and a second electrode C12 of the second capacitor Cb may be arranged on the second buffer layer 112. The semiconductor layer Act1 of the second thin-film transistor TFTc, the semiconductor layer Act2 of the third thin-film transistor TFTo, and the second electrode C12 of the second capacitor Cb may include an oxide semiconductor material. The oxide semiconductor material may include an oxide of at least one material selected from a group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The oxide semiconductor material may be In-Ga-Zn-O (IGZO), In-Sn-Zn-O (ITZO), or In-Ga-Sn-Zn-O (IGTZO). The second electrode C12 of the second capacitor Cb may be an oxide semiconductor material that is doped with impurities to be electrically conductive. The semiconductor layer Act1 of the second thin-film transistor TFTc, the semiconductor layer Act2 of the third thin-film transistor TFTo, and the second electrode C12 of the second capacitor Cb may be arranged on the same layer as the semiconductor layer Act3 of the first thin-film transistor TFTp.

Each of the semiconductor layer Act1 of the second thin-film transistor TFTc and the semiconductor layer Act2 of the third thin-film transistor TFTo may include a channel area, and a source area and a drain area arranged at opposite sides of the semiconductor layer Act1 or Act2. A gate electrode GE1 of the second thin-film transistor TFTc may overlap the channel area of the semiconductor layer Act1. A gate electrode GE2 of the third thin-film transistor TFTo may overlap the channel area of the semiconductor layer Act2. Each of the gate electrode GE1 of the second thin-film transistor TFTc and the gate electrode GE2 of the third thin-film transistor TFTo may be arranged on the same layer as a gate electrode GE3 of the first thin-film transistor TFTp. The gate insulating layer 113 may be arranged between the semiconductor layer Act1 and the gate electrode GE1 of the second thin-film transistor TFTc, and between the semiconductor layer Act2 and the gate electrode GE2 of the third thin-film transistor TFTo.

The interlayer insulating layer 114 may be arranged on the gate electrode GE1 of the second thin-film transistor TFTc, the gate electrode GE2 of the third thin-film transistor TFTo, and the second electrode C12 of the second capacitor Cb. A third electrode C13 of the second capacitor Cb and first wirings WL1 may be arranged on the interlayer insulating layer 114. Each of the third electrode C13 of the second capacitor Cb and the first wirings WL1 may be arranged on the same layer as the second connection electrode 131.

In a plan view, the first electrode C11, the second electrode C12, and the third electrode C13 of the second capacitor Cb may overlap one another. In an embodiment, any one of the first electrode C11, the second electrode C12, and the third electrode C13 may be electrically connected to the second terminal S2 (see FIG. 4) of the stage ST (see FIG. 4), and the other one of the first electrode C11, the second electrode C12, and the third electrode C13 may be electrically connected to the second control node NQB of the node control circuit NC. The second capacitor Cb is a buffer capacitor for stably maintaining a voltage of a gate signal and may be arranged adjacent to the display area DA.

The first planarization layer 115 may be arranged on the first wirings WL1 and the third electrode C13 of the second capacitor Cb, and second wirings WL2 may be arranged on the first planarization layer 115. Each of the second wirings WL2 may be arranged on the same layer as the third connection electrode 133.

The second planarization layer 116 may be arranged on the second wirings WL2, and third wirings WL3 and the first connection electrode 140 may be arranged on the second planarization layer 116. The third wirings WL3 and the first connection electrode 140 may be arranged on the same layer as the pixel electrode 210 of the organic light-emitting diode OLED.

In a plan view, a first wiring WL1, a second wiring WL2, and a third wiring WL3 that overlap one another may be electrically connected and form the clock line CKL. In other words, each of the first to fourth clock lines CKL1, CKL2, CKL3, and CKL4 may include the first wiring WL1, the second wiring WL2 arranged on the first wiring WL1, and the third wiring WL3 arranged on the second wiring WL2, and the first wiring WL1, the second wiring WL2, and the third wiring WL3 included in the same clock line CKL may be electrically connected to each other. The clock lines CKL may have a triple-layer structure and thus may have relatively low resistance. The first to fourth clock lines CKL1, CKL2, CKL3, and CKL4 may be spaced apart from each other in the first direction (for example, the x direction).

The first connection electrode 140 may partially overlap the second area 2A. For example, in a plan view, the first connection electrode 140 may overlap the second thin-film transistor TFTc and the third thin-film transistor TFTo. In a plan view, the first connection electrode 140 may be spaced apart from the clock lines CKL. The first connection electrode 140 may not overlap the clock line CKL, resulting in a decrease in capacitance between the first connection electrode 140 and the clock line CKL. Therefore, a rising time and a falling time of a gate signal output from the first driving circuit SDRV1 may be reduced, thereby achieving an output of a high-quality image from the display panel 10.

In an embodiment, in a plan view, the first connection electrode 140 may be spaced apart from the second capacitor Cb. The first connection electrode 140 may not overlap the second capacitor Cb, but the disclosure is not limited thereto. The first connection electrode 140 may define the plurality of holes 140h for discharging gas generated from lower organic layers.

The bank layer 119 may be arranged on the first connection electrode 140 and the clock lines CKL. The bank layer 119 may include an opening extending to a top surface of the first connection electrode 140. The common electrode 230 may be arranged on the bank layer 119. The common electrode 230 may be in direct contact with the top surface of the first connection electrode 140 via the opening of the bank layer 119. The first connection electrode 140 may electrically connect the common voltage supply line 13 to the common electrode 230. In the display panel 10, the clock lines CKL are arranged adjacent to the display area DA, thereby maximizing a contact area CTA where the first connection electrode 140 and the common electrode 230 are in contact with each other.

An encapsulation layer may be arranged on the common electrode 230. The encapsulation layer may include at least one organic insulating layer and at least one inorganic insulating layer. For example, the encapsulation layer may include a first inorganic encapsulation layer, a second inorganic encapsulation layer, and an organic encapsulation layer between the first inorganic encapsulation layer and the second inorganic encapsulation layer.

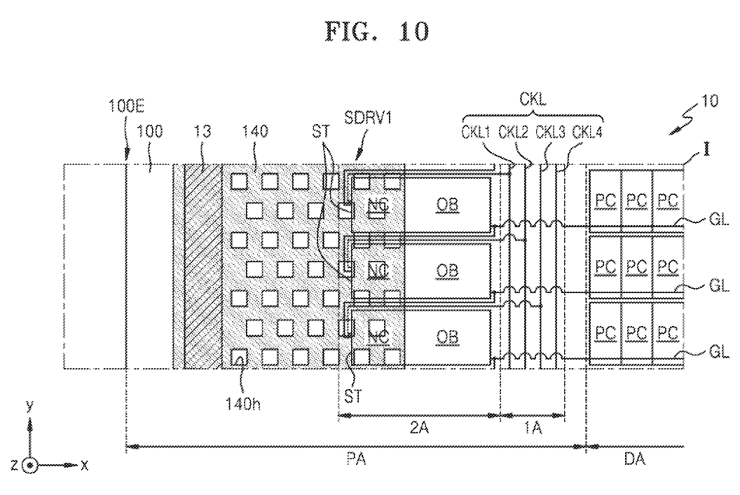

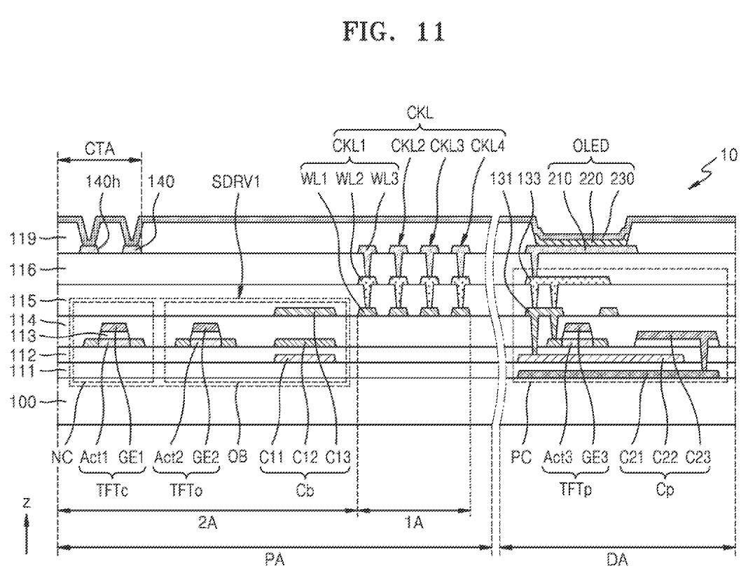

FIG. 10 is a schematic view showing a portion of a display panel according to an embodiment, and FIG. 11 is a cross-sectional view schematically illustrating a display panel according to an embodiment.

Referring to FIG. 10, the display area DA and the peripheral area PA surrounding at least a portion of the display area DA may be defined on the substrate 100. The plurality of pixel circuits PC may be arranged in the display area DA. The pixel circuits PC arranged in the same row may be electrically connected to the same gate line GL. Switching transistors electrically connected to the same gate line GL may be simultaneously turned on or turned off in response to a gate signal transmitted via the gate line GL.

The common voltage supply line 13 may be arranged in the peripheral area PA. The common voltage supply line 13 may extend along the edge 100E of the substrate 100. The clock lines CKL may be arranged in the peripheral area PA, which is adjacent to the display area DA. The clock lines CKL may include the first to fourth clock lines CKL1, CKL2, CKL3, and CKL4.

The clock lines CKL may be arranged in the first area 1A of the peripheral area PA, and the first driving circuit SDRV1 may be arranged in the second area 2A of the peripheral area PA. The first area 1A may be arranged between the second area 2A and the display area DA.

The first driving circuit SDRV1 may include a plurality of stages ST. Each of the plurality of stages ST may be connected to a corresponding clock line. Each of the plurality of stages ST may include the node control circuit NC and the output circuit OB. The node control circuit NC may be arranged closer to the edge 100E of the substrate 100 than the output circuit OB. The output circuit OB may be arranged closer to the display area DA than the node control circuit NC. The clock lines CKL may be arranged at a side closer to the output circuit OB.

The first connection electrode 140 may be arranged in the peripheral area PA. The first connection electrode 140 may be arranged on the common voltage supply line 13 and the first driving circuit SDRV1 and may electrically connect a common electrode of an organic light-emitting diode to the common voltage supply line 13.

In a plan view, the first connection electrode 140 may overlap the common voltage supply line 13 and the first driving circuit SDRV1. An inner edge of the first connection electrode 140 may be arranged on the first driving circuit SDRV1. For example, the first connection electrode 140 may entirely cover the node control circuit NC and may be spaced apart from the output circuit OB. In other words, the first connection electrode 140 may not overlap the output circuit OB and the clock lines CKL. As a distance between the first connection electrode 140 and the clock lines CKL increases, a capacitance between the first connection electrode 140 and the clock lines CKL may decrease. The first connection electrode 140 may define the plurality of holes 140h through which gas generated from lower organic layers is discharged.

Referring to FIG. 11, the display panel 10 may include the substrate 100. The display area DA and the peripheral area PA surrounding at least a portion of the display area DA may be defined on the substrate 100. Each of pixels arranged in the display area DA may include the pixel circuit PC and the organic light-emitting diode OLED electrically connected to the pixel circuit PC. The pixel circuit PC may include the first thin-film transistor TFTp and the first capacitor Cp.

The first driving circuit SDRV1 and the clock lines CKL may be arranged in the peripheral area PA. The first driving circuit SDRV1 may include a plurality of stages, and each of the stages may include the node control circuit NC and the output circuit OB. The node control circuit NC may include the second thin-film transistor TFTc, and the output circuit OB may include the third thin-film transistor TFTo and the second capacitor Cb (the buffer capacitor). The clock lines CKL may include the first to fourth clock lines CKL1, CKL2, CKL3, and CKL4.T

The first buffer layer 111 may be arranged on the substrate 100, and the second buffer layer 112 may be arranged on the first buffer layer 111. The first electrode C21 of the first capacitor Cp may be arranged between the substrate 100 and the first buffer layer 111, and the second electrode C22 of the first capacitor Cp may be arranged between the first buffer layer 111 and the second buffer layer 112.

The semiconductor layer Act3 of the first thin-film transistor TFTp may be arranged on the second buffer layer 112. The semiconductor layer Act3 of the first thin-film transistor TFTp may include an oxide semiconductor material. The upper gate electrode GE3 of the first thin-film transistor TFTp may overlap the channel area of the semiconductor layer Act3. The gate insulating layer 113 may be arranged between the semiconductor layer Act3 and the upper gate electrode GE3 of the first thin-film transistor TFTp.

The third electrode C23 of the first capacitor Cp may be arranged on the second buffer layer 112. The third electrode C23 may be arranged on the same layer as the upper gate electrode GE3 of the first thin-film transistor TFTp. The gate insulating layer 113 may be arranged between the second buffer layer 112 and the third electrode C23 of the first capacitor Cp. In a plan view, the first electrode C21, the second electrode C22, and the third electrode C23 of the first capacitor Cp may overlap one another.

The interlayer insulating layer 114 may be arranged on the upper gate electrode GE3 of the first thin-film transistor TFTp and the third electrode C23 of the first capacitor Cp. The second connection electrode 131 may be arranged on the interlayer insulating layer 114. The second connection electrode 131 may be electrically connected to the source area (or the drain area) of the first thin-film transistor TFTp via a contact hole passing through the interlayer insulating layer 114. The first planarization layer 115 may be arranged on the second connection electrode 131, and the third connection electrode 133 may be arranged on the first planarization layer 115. The third connection electrode 133 may be electrically connected to the second connection electrode 131 via a contact hole passing through the first planarization layer 115. The second planarization layer 116 may be arranged on the third connection electrode 133.

The organic light-emitting diode OLED may be arranged on the second planarization layer 116. The organic light-emitting diode OLED may include the pixel electrode 210, the emission layer 220, and the common electrode 230.

The pixel electrode 210 may be arranged on the second planarization layer 116. The pixel electrode 210 may be electrically connected to the first thin-film transistor TFTp of the pixel circuit PC via the second connection electrode 131 and the third connection electrode 133.

The bank layer 119 may be arranged on the pixel electrode 210. An opening extending to at least a portion of the pixel electrode 210 may be defined in the bank layer 119. The common electrode 230 may be arranged on the emission layer 220. In an embodiment, the common electrode 230 may be arranged on the plurality of pixel electrodes 210 and entirely cover the display area DA.

The peripheral area PA may include the first area 1A and the second area 2A outside the first area 1A. The clock lines CKL may be arranged in the first area 1A, and the first driving circuit SDRV1 may be arranged in the second area 2A.

The first driving circuit SDRV1 may include a plurality of stages, and each of the stages may include the node control circuit NC and the output circuit OB. The node control circuit NC may include the second thin-film transistor TFTc, and the output circuit OB may include the third thin-film transistor TFTo and the second capacitor Cb.

The second capacitor Cb may include the first electrode C11 arranged between the first buffer layer 111 and the second buffer layer 112, the second electrode C12 arranged between the second buffer layer 112 and the interlayer insulating layer 114, and the third electrode C13 arranged between the interlayer insulating layer 114 and the first planarization layer 115.

The second thin-film transistor TFTc may include the semiconductor layer Act1 arranged on the second buffer layer 112 and the gate electrode GE1 on the semiconductor layer Act1. The third thin-film transistor TFTo may include the semiconductor layer Act2 arranged on the second buffer layer 112 and the gate electrode GE2 on the semiconductor layer Act2. The gate insulating layer 113 may be arranged between the semiconductor layer Act1 and the gate electrode GE1 of the second thin-film transistor TFTc, and between the semiconductor layer Act2 and the gate electrode GE2 of the third thin-film transistor TFTo. The semiconductor layer Act1 of the second thin-film transistor TFTc and the semiconductor layer Act2 of the third thin-film transistor TFTo may include an oxide semiconductor material. In other words, each of the second thin-film transistor TFTc and the third thin-film transistor TFTo may be an oxide thin-film transistor.

Each of the clock lines CKL may include the first wiring WL1, the second wiring WL2, and the third wiring WL3 that overlap one another in a plan view. The first wiring WL1 may be arranged between the interlayer insulating layer 114 and the first planarization layer 115, the second wiring WL2 may be arranged between the first planarization layer 115 and the second planarization layer 116, and the third wiring WL3 may be arranged between the second planarization layer 116 and the bank layer 119. The third wirings WL3 may be arranged on the same layer as the pixel electrode 210 of the organic light-emitting diode OLED. The clock lines CKL may have a triple-layer structure and thus may have relatively low resistance.

The first connection electrode 140 may be arranged between the second planarization layer 116 and the bank layer 119. The first connection electrode 140 may be arranged on the same layer as the pixel electrode 210 of the organic light-emitting diode OLED. The first connection electrode 140 may partially overlap the second area 2A. For example, in a plan view, the first connection electrode 140 may overlap the node control circuit NC. The first connection electrode 140 may define the plurality of holes 140h for discharging gas generated from lower organic layers.

In a plan view, the first connection electrode 140 may not cover (e.g., be spaced apart from) the clock lines CKL and the output circuit OB. Therefore, a distance between the first connection electrode 140 and the clock lines CKL increases, and thus, a capacitance between the first connection electrode 140 and the clock lines CKL may be reduced. Therefore, a rising time and a falling time of a gate signal output from the first driving circuit SDRV1 may be reduced, thereby achieving an output of a high-quality image from the display panel 10.

The bank layer 119 may be arranged on the first connection electrode 140 and the clock lines CKL. The bank layer 119 may include an opening extending to the top surface of the first connection electrode 140. The common electrode 230 may be arranged on the bank layer 119. The common electrode 230 may be in direct contact with the top surface of the first connection electrode 140 via the opening of the bank layer 119. Because the clock lines CKL and the output circuits OB are arranged adjacent to the display area DA, the area of the contact area CTA in which the first connection electrode 140 and the common electrode 230 are in contact with each other may be sufficiently secured.

An encapsulation layer may be arranged on the common electrode 230. The encapsulation layer may include at least one organic insulating layer and at least one inorganic insulating layer.

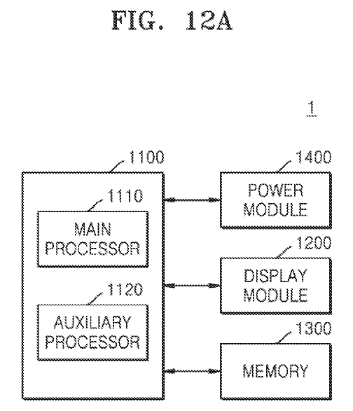

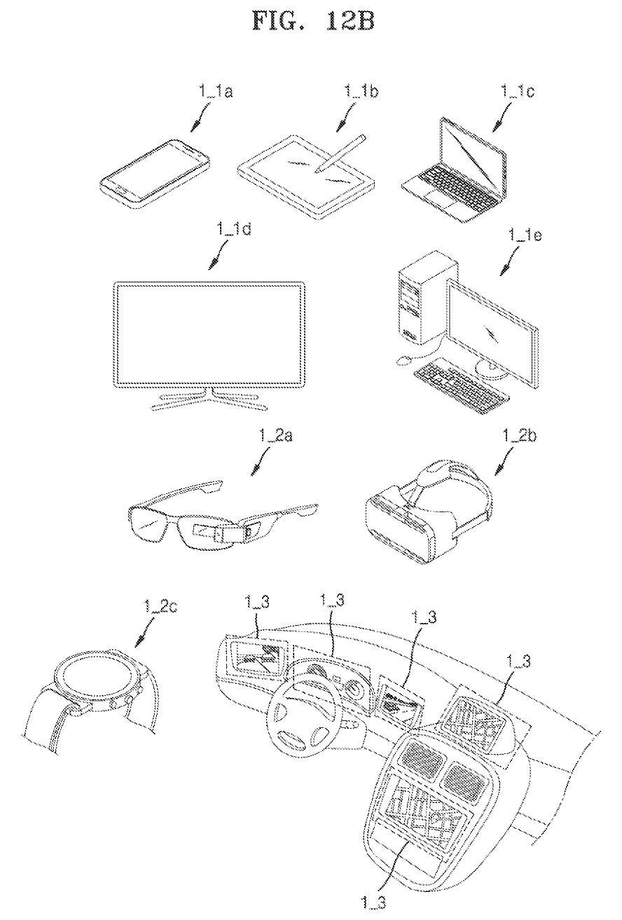

FIG. 12A is a block diagram of an electronic apparatus according to an embodiment. Referring to FIG. 12A, an electronic apparatus 1 according to an embodiment may include a processor 1100, a display module 1200, a memory 1300, and a power module 1400.

The processor 1100 may include at least one of a central processing unit (CPU), an application processor (AP), a graphics processing unit (GPU), a communication processor (CP), an image signal processor (ISP), and a controller. In an embodiment, the processor 1100 may be provided as two or more separate units from a functional or structural perspective. For example, the processor 1100 may include a main processor 1110, which may be implemented as a first driving chip including a CPU, and an auxiliary processor 1120, which may be implemented as a second driving chip including a controller. The auxiliary processor 1120 receives an image signal from the main processor 1110, processes the image signal to satisfy interface specifications of the display module 1200, and generates an image data signal.

The controller may supply a data driving control signal and a gate driving control signal to the display module 1200. Each of the data driving control signal and the gate driving control signal may include a plurality of clock signals and a start signal. The controller may supply a power driving control signal to the power module 1400, and the power module 1400 may generate the plurality of clock signals and the start signal and supply them to the display module 1200.

The display module 1200 may include the display panel 10. The memory 1300 may store data information required to operate the processor 1100 or the display module 1200. When the processor 1100 executes an application stored in the memory 1300, an image data signal and/or an input control signal may be transmitted to the display module 1200, and the display module 1200 may process the received signal and output image information via a display screen.

The power module 1400 may include a power supply module, such as a power adapter or a battery apparatus, and a power conversion module that converts power supplied by the power supply module and generates power required to operate the electronic apparatus 1. The power module 1400 is a power supply circuit configured to drive components of the display module 1200 and may include a power management integrated circuit (PMIC). The PMIC may supply optimized power to each of the components of the display module 1200.

In an embodiment, the power module 1400 may generate signals (high-level voltage, low-level voltage, and current) required to operate the display module 1200, in response to a control signal from the processor 1100. When the display module 1200 includes an organic light-emitting display panel, the power module 1400 may generate a first power voltage and a second power voltage and supply them to pixels. The first power voltage may be a high-level voltage provided to one terminal of a driving transistor connected to a pixel electrode of an organic light-emitting diode. The second power voltage may be a low-level voltage provided to a common electrode of the organic light-emitting diode.

Some of the components of the electronic apparatus 1 may be included in the display module 1200. In addition, some of individual modules functionally included within one module may be included in the display module 1200, and some others may be provided separately from the display module 1200. For example, the processor 1100, the memory 1300, and the power module 1400 may be provided in a form which drives other modules within the electronic apparatus 1.

FIG. 12B shows schematic views of electronic apparatuses according to various embodiments.

Referring to FIG. 12B, various electronic apparatuses, to which a display module according to embodiments is applied, may include not only image display electronic apparatuses, such as a smartphone 1_1a, a tablet PC 1_1b, a laptop 1_1c, a TV 1_1d, and a desk monitor 1_1e, but also wearable electronic apparatuses including a display module, such as smart glasses 1_2a, a head-mounted display 1_2b, and a smart watch 1_2c. The electronic apparatuses, to which a display module according to embodiment is applied, may further include vehicle electronic apparatuses 1_3 including a display module, such as an instrument panel of a vehicle, a center information display (CID) arranged on a center fascia or dashboard, and a room mirror display.

According to an embodiment as described above, a display panel, which displays a high-quality image by reducing a rising time and a falling time of a gate signal, and an electronic apparatus including the same may be implemented. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While the inventive concept of the disclosure has been described with reference to the drawings and embodiments thereof, it will be understood by those of ordinary skill in the art that various changes in form and details may be made thereto without departing from the spirit and scope of the disclosure as set forth and defined by the following claims.

What is claimed is:

1. A display panel comprising:
a substrate comprising a display area and a peripheral area outside the display area;
a plurality of pixels arranged in the display area;
a driving circuit arranged in the peripheral area and configured to output a plurality of gate signals to the plurality of pixels; and
a plurality of clock lines arranged between the driving circuit and the display area and electrically connected to the driving circuit.

2. The display panel of claim 1, further comprising:
a common voltage supply line arranged in the peripheral area and surrounding at least a portion of the display area; and
wherein the connection electrode is electrically connected to the common voltage supply line and overlapping at least of the driving circuit,
wherein the connection electrode is spaced apart from the plurality of clock lines in a plan view.

3. The display panel of claim 2, wherein the driving circuit comprises a plurality of stages, and
each of the plurality of stages comprises:
a node control circuit configured to control voltage levels of a first control node and a second control node; and
an output circuit comprising a pull-up transistor that is turned on or turned off in response to a voltage level of the first control node and a pull-down transistor that is turned on or turned off in response to a voltage level of the second control node.

4. The display panel of claim 3, wherein the output circuit further comprises a buffer capacitor, and
the connection electrode is spaced apart from the buffer capacitor in the plan view.

5. The display panel of claim 3, wherein the connection electrode overlaps the node control circuit and is spaced apart from the output circuit in the plan view.

6. The display panel of claim 2, wherein each of the plurality of pixels comprises:
a pixel electrode;
a common electrode arranged on the pixel electrode; and
an emission layer arranged between the pixel electrode and the common electrode, and
wherein the connection electrode is electrically connected to the common electrode.

7. The display panel of claim 6, wherein the connection electrode is arranged on a same layer as the pixel electrode.

8. The display panel of claim 6, wherein each of the plurality of clock lines comprises:
a first wiring;
a second wiring arranged on the first wiring; and
a third wiring arranged on the second wiring, and
wherein the first wiring, the second wiring, and the third wiring are electrically connected to each other.

9. The display panel of claim 8, wherein the third wiring is arranged on a same layer as the pixel electrode.

10. The display panel of claim 1, wherein the driving circuit comprises a plurality of transistors, and
wherein the plurality of transistors are oxide thin-film transistors.

11. An electronic apparatus comprising:
a main processor;
a display panel displaying an image based on an image data signal; and
a controller electrically connected to the display panel and configured to receive an image signal from the main processor, generate the image data signal, and output a plurality of clock signals and the image data signal to the display panel,
wherein the display panel comprises:
a substrate comprising a display area and a peripheral area outside the display area;
a plurality of pixels arranged in the display area;
a driving circuit arranged in the peripheral area and configured to output a plurality of gate signals to the plurality of pixels in response to the plurality of clock signals; and
clock lines arranged between the driving circuit and the display area and configured to transmit the plurality of clock signals to the driving circuit.

12. The electronic apparatus of claim 11, wherein the display panel further comprises:
a common voltage supply line arranged in the peripheral area and surrounding at least a portion of the display are; and
a connection electrode electrically connected to the common voltage supply line and overlapping at least a portion of the driving circuit,
wherein the connection electrode is electrically connected to the common voltage supply line,
wherein the connection electrode is spaced apart from the clock lines in a plan view.

13. The electronic apparatus of claim 12, wherein the driving circuit comprises a plurality of stages, and
each of the plurality of stages comprises:
a node control circuit configured to control voltage levels of a first control node and a second control node; and
an output circuit comprising a pull-up transistor that is turned on or turned off in response to a voltage level of the first control node and a pull-down transistor that is turned on or turned off in response to a voltage level of the second control node.

14. The electronic apparatus of claim 13, wherein the output circuit further comprises a buffer capacitor, and
the connection electrode is spaced apart from the buffer capacitor in the plan view.

15. The electronic apparatus of claim 13, wherein the connection electrode overlaps the node control circuit and is spaced apart from the output circuit in the plan view.

16. The electronic apparatus of claim 12, wherein each of the plurality of pixels comprises:
a pixel electrode;
a common electrode arranged on the pixel electrode; and
an emission layer arranged between the pixel electrode and the common electrode, and
wherein the connection electrode is electrically connected to the common electrode.

17. The electronic apparatus of claim 16, wherein the connection electrode is arranged on a same layer as the pixel electrode.

18. The electronic apparatus of claim 16, wherein each of the clock lines comprises:
a first wiring;
a second wiring arranged on the first wiring; and
a third wiring arranged on the second wiring, and
wherein the first wiring, the second wiring, and the third wiring are electrically connected to each other.

19. The electronic apparatus of claim 18, wherein the third wiring is arranged on a same layer as the pixel electrode.

20. The electronic apparatus of claim 11, wherein the electronic apparatus is one of an image display electronic apparatus, a wearable electronic apparatus, and a vehicle electronic apparatus.
